(19) United States
(12) Patent Application Publication
(10) Pub. No.: US 2010/0017155 A1
(43) Pub. Date: Jan. 21, 2010

(54) BATTERY MANAGEMENT SYSTEM

(75) Inventor: Helge Nareid, Aberdeen (GB)

Correspondence Address: KLEIN, O'NEILL & SINGH, LLP, 43 CORPORATE PARK, SUITE 204, IRVINE, CA, 92606, US

(73) Assignee: ITI SCOTLAND LIMITED

(21) Appl. No.: 12/517,545

(22) PCT Filed: Apr. 20, 2007
(86) PCT No.: PCT/GB2007/001435

§ 371 Date: Jun. 3, 2009

(30) Foreign Application Priority Data
Dec. 6, 2006 (GB) 0624450.3

(51) Int. Cl. G01R 31/36

(52) U.S. Cl. 702/63

(57) ABSTRACT

A battery management system includes a neural network, for estimating an amount of charge stored in a battery following a recharging operation. Then, an amount of charge drawn during a discharging operation is subtracted from this estimated amount of charge to derive an estimate for the state of charge of the battery at a present time. A parameter representing the state of health of the battery may be provided as an input to the neural network, and the parameter representing the state of health of the battery may be generated by a second neural network.

### CROSS-REFERENCE TO RELATED APPLICATION

This application is a national phase filing, under 35 U.S.C. §371 (c), of International Application No. PCT/GB2007/001435, filed Apr. 20, 2007, the disclosure of which is incorporated herein by reference in its entirety.

### FEDERALLY SPONSORED RESEARCH OR DEVELOPMENT

Not Applicable

### BACKGROUND

This invention relates to a system for monitoring the status of an electrochemical cell, or a battery including more than one such cell.

Electrochemical cells are widely used, to provide power to a wide range of equipment. Small batteries are used to provide electric power to portable electronic devices such as mobile phones and laptop computers, while larger batteries are used to provide power for vehicles, either alone in the case of electric vehicles (EVs) or in combination with internal combustion engines in the case of hybrid electric vehicles (HEVs).

In any application, it can be desirable to know the status of a cell, or of the multiple cells making up a battery. In particular, it can be desirable to know the amount of stored charge remaining in the cell. For example, in the case of rechargeable cells, knowing the amount of stored charge remaining can provide a user with an indication as to when the cell should be recharged.

Where a cell is periodically fully recharged, it is possible to obtain one estimate of the amount of stored charge remaining by measuring the amount of charge that has been drawn from the cell since it was last fully recharged. However, this has the shortcoming that the maximum amount of charge that can be held by the cell (that is, the amount of charge held by the cell when it has apparently been fully charged) is not constant, but rather varies with time, tending to decline with each charging and recharging cycle. Where a cell is also periodically fully discharged, the measured amount of charge drawn from the cell during the discharging operation can be taken to be the maximum amount of charge that can be held by the cell, and this value will probably be a reasonable estimate for at least one future charging and discharging cycle, so the measured amount of charge drawn from the cell during that future discharging process can be used to give a reasonable estimate of the charge remaining.

However, fully discharging the cell is often inconvenient for the user or detrimental to the condition of the cell, or both, and so this measurement technique is often not suitable.

It is known to use an artificial neural network to estimate the state of charge of a cell. For example, US 2005/0194936 discloses a system in which a current, a voltage, and a temperature of a battery cell are detected, and applied to a neural network. Based on its neural network algorithm, established through a learning algorithm, the neural network outputs a value for the state of charge (SOC) of the battery.

However, as the state of charge is a relatively quickly varying parameter, the artificial neural network output will tend to be relatively sensitive to noise in its input values, and may not produce a particularly reliable estimate of the state of charge.

### SUMMARY

According to a first aspect of the present invention, there is provided a method of estimating a state of charge of a battery, comprising:
using a first neural network to form an estimate of a remaining amount of charge following a previous recharging operation;
measuring an amount of charge drawn from the battery since the previous recharging operation;
forming an estimate of the state of charge from the estimated remaining amount of charge and the amount of charge drawn.

This has the advantage that, by using the first neural network to estimate a relatively slowly varying quantity, a more reliable estimate can be obtained.

Moreover, this method has the advantage that an estimate of the state of charge can be obtained without needing to discharge the battery.

According to a second aspect of the present invention, there is provided a battery management system, for estimating a state of charge of a battery, comprising:
a first neural network, for forming an estimate of a remaining amount of charge following a previous recharging operation;
means for measuring an amount of charge drawn from the battery since the previous recharging operation; and
means for forming an estimate of the state of charge from the estimated remaining amount of charge and the amount of charge drawn.

According to a third aspect of the present invention, there is provided an electrochemical cell system comprising a battery management system according to the second aspect of the present invention.

### BRIEF DESCRIPTION OF THE DRAWINGS

FIG. 1 is a schematic diagram of an electrically powered system, in accordance with an aspect of the invention.

FIG. 2 is a schematic diagram illustrating in more detail a parameter estimator in accordance with an aspect of the invention.

### DETAILED DESCRIPTION

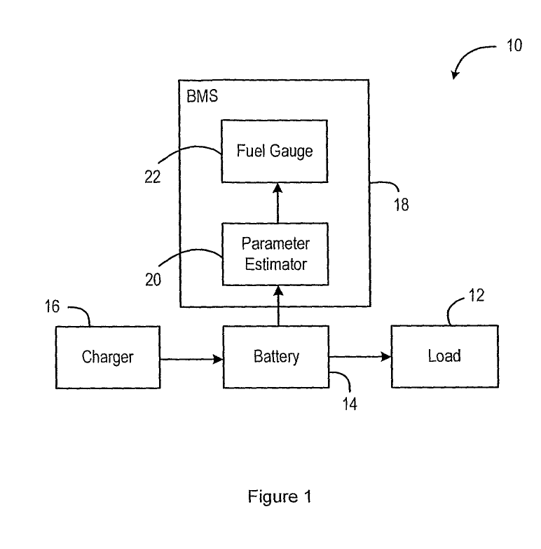

FIG. 1 is a schematic diagram showing an electrical system 10 in accordance with an aspect of the invention. The system 10 includes a load device 12 that is being powered by a battery 14. The load device 12 can be any electrically powered electrical or electronic device, and the battery 14 is chosen to be suitable for powering the load device 12. For example, the load device 12 can be an electronic device such as a mobile phone or a laptop computer, in which case the battery 14 may be relatively small, with a correspondingly small charge capacity, or the load device 12 may be an electric vehicle (EV) or a hybrid electric vehicle (HEV), in which case the battery 14 needs to be larger, with a larger charge capacity. When this is appropriate for the application in question, the battery 14 can include a single electrochemical cell.

The battery 14 can be based on any electrochemical energy storage technology. For example, in one embodiment, the battery 14 includes a series of lithium-ion (Li-Ion) cells.

In the illustrated embodiment, the battery 14 is a rechargeable battery, and is shown connected to a charger 16, which supplies electrical power to the battery 14 to recharge it. However, the invention is in principle also applicable to non-rechargeable batteries, in applications where it is nevertheless desirable to know the status of the battery.

It will also be appreciated that, in use, the battery 14 and the load device 12 may be disconnected from the charger 16, for portable operation, and subsequently reconnected to the charger for recharging.

Also, although the charger 16 is shown as a separate device from the load device 12, the invention is also applicable to an arrangement in which the battery 14 is recharged from the load device 12, for example as in a hybrid electric vehicle (HEV), using regenerative braking.

As mentioned previously, it can be desirable to know the amount of stored charge remaining in the battery 14. For example, in the case of rechargeable batteries, knowing the amount of stored charge remaining can provide a user with an indication as to when the battery should be recharged.

For this purpose, the battery is provided with a battery management system (BMS), which in this illustrated embodiment of the invention includes a parameter estimator 20 and a fuel gauge 22. The parameter estimator 20 is connected to receive inputs from the battery 14, and estimate values for one or more parameters relevant to the operation of the battery 14. One or more such parameter is provided to the fuel gauge 22 for display to a user of the device. For example, the fuel gauge 22 may be a numerical display of one or more relevant parameter such as a usage time remaining, or may simply provide a warning when the battery 14 is nearly discharged, or may include an analog display showing the remaining battery capacity, or may take any other convenient form.

As is well known, the battery 14 will typically include more than one electrochemical cell connected in series to provide a required electrical voltage, in which case the battery management system 18 may either receive a single set of inputs for the battery as a whole, or it may receive separate inputs from each cell, in which case it may then either combine them to provide parameters relevant to the operation of the battery 14 as a whole, or it may provide separate parameter values for each cell.

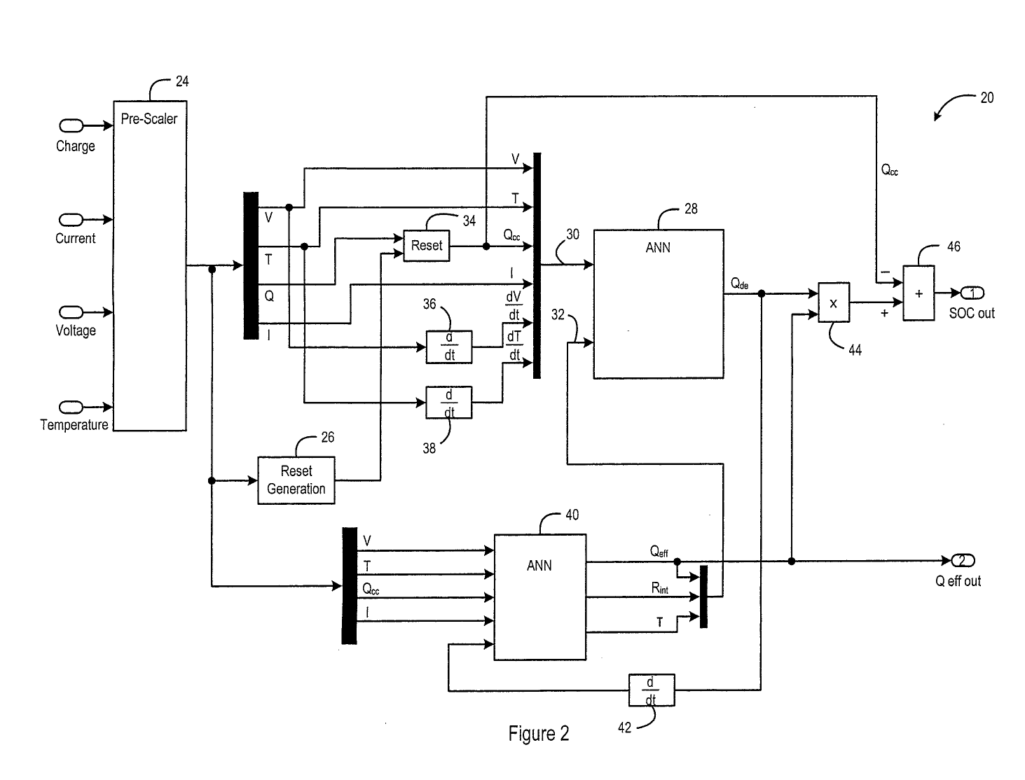

FIG. 2 is a block schematic diagram, illustrating the operation of the parameter estimator 20.

In this illustrative example, the parameter estimator 20 receives four input values from the battery 14, namely the current (I), the charge (Q), the voltage (V), and the temperature (T). The current (I) is the amount of current being supplied from the battery 14 to the load device 12. The charge (Q) is the total amount of charge that has been drawn from the battery 14, and can be obtained by integrating the current (I). The technique for determining an amount of charge drawn from a battery by integrating the current is often referred to as “Coulomb counting”. The voltage (V) is the output voltage of the battery 14, which will vary depending on the status of the battery 14, and the temperature (T) is the temperature of the battery 14, as detected by a suitably located temperature sensor.

These four input values are applied to a pre-scaler 24, which scales the input values, and converts them into a required format. The formatted values are supplied to a reset signal generator 26, which generates a reset signal when it has been determined that the battery 14 has been fully recharged. For example, it can be determined that the battery 14 has been fully recharged when the voltage and the charging current have reached a set of predetermined cut-off values.

The parameter estimation is performed by an artificial neural network (ANN) 28, which in this embodiment of the invention is a modular map neural network, of the type described in EP-A-1149359, although any convenient type of artificial neural network can be used, provided that it has been suitably trained on the required form of input data.

In this illustrated embodiment, the inputs to the neural network 28 during operation are an input vector 30 and a state vector 32. The input vector 30 includes the scaled and formatted values for the current (I), the voltage (V), and the temperature (T) received from the battery 14. In addition, the scaled and formatted value for the charge (Q) is applied to a reset block 34, where the input value is reset in response to a signal from the reset generator 26, and the resulting output value (Q_{CC}) is also supplied as part of the input vector 30. Thus, the charge value (Q_{CC}) forming part of the input vector 30 represents the charge supplied by the battery 14 since it was last fully charged.

Further, the scaled and formatted value for the voltage (V) is applied to a differentiator 36, and the resulting time derivative of the voltage (dV/dt) is also supplied as part of the input vector 30, and the scaled and formatted value for the temperature (T) is applied to a further differentiator 38, and the resulting time derivative of the temperature (dT/dt) is also supplied as part of the input vector 30.

In this embodiment of the invention, the neural network 28 provides an estimate for an output parameter that can be used to estimate the state of charge of the battery 14. However, rather than estimating directly the amount of charge remaining in the battery 14, the neural network 28 provides an estimate for the total charge available in the cell at the start of the ongoing discharge operation. This parameter is referred to as Q_{de}.

In order to be able to produce the required estimate, the neural network 28 is also supplied with an input state vector 32, containing information about various parameters relevant to the health of the battery 14. In this illustrated embodiment of the invention, the state vector 32, representing the state of health of the battery 14, is output from a second artificial neural network (ANN) 40, which again in this embodiment of the invention is a modular map neural network, of the type described in EP-A-1149359, although any convenient type of artificial neural network can be used, provided that it has been suitably trained on the required form of input data.

The second neural network 40 receives as inputs the scaled and formatted values for the four input values from the battery 14, namely the current (I), the charge (Q_{CC}), the voltage (V), and the temperature (T), processed by the pre-scaler 24.

The second neural network 40 also receives a feedback input from the first neural network 28, as will be discussed in more detail below.

The second neural network 40 then generates the state vector 32, for input to the first neural network 28. This state vector 32 contains information about various parameters relevant to the health of the battery 14. In this illustrative example, it contains estimated values for the effective capacity of the battery 14 (Q_{eff}), the internal resistance of the battery 14 (Rᵢₙₜ), and the time constant (τ) resulting from the resistances and capacitances of an equivalent circuit of the battery 14, but other parameters or combinations of parameters can be used in addition or alternatively.

The estimated value (Q_{eff}) for the effective capacity of the battery 14 can be regarded as constant over any particular charge/discharge cycle, but will vary over time as the battery 14 ages.

A system is described here in which a second neural network 40 generates the state vector 32, containing information about various parameters relevant to the health of the battery 14, for input to the first neural network 28. However, in an alternative system, the relevant parameter values can be obtained or estimated in other ways. For example, using the parameters discussed above, the internal resistance of the battery 14 (Rᵢₙₜ) can be estimated by comparing the battery terminal voltages at two different current levels (one of which may conveniently be zero), the time constant (τ) is the time constant with which the terminal voltage settles to a specific level following recharging (and can be estimated from a small set of voltage measurements obtained at set time intervals after recharging), while the effective capacity of the battery 14 (Q_{eff}) can be set initially to a predetermined level, and then adjusted based on feedback from the output from the first artificial neural network 28.

In one embodiment, the second neural network 40 can in effect be formed from two neural networks, with a first of these forming an estimate for the battery impedance, which in turn is passed to the second of these two neural networks. Where a directly measured, or inferred, or modelled value is available for the battery impedance, then this can be used to avoid the need for a neural network to form an estimate for the battery impedance. Indeed, where a directly measured, or inferred, or modelled value is available for the battery impedance, this can be supplied directly to the first neural network 28 as part of the state vector 32. For example, a value can be obtained for the battery impedance by means of a Digital Signal Processor, on the basis of received voltage and current values.

Although the total charge available in the cell at the start of the ongoing discharge operation (Q_{de}) is closely related to the effective capacity of the battery 14 (Q_{eff}), these parameters are not the same. Specifically, the effective capacity of the battery 14 (Q_{eff}) is defined for a specific set of operational conditions, such as the temperature and the current drain. Thus, the total charge available (Q_{de}) is a function of Q_{eff} and of environmental and operational parameters. As such, the value of Q_{de} can vary even while Q_{eff} remains constant, for example if the temperature drops or the current demand increases.

In this example, the value of Q_{de} is expressed as a percentage of Q_{eff}. The value of Q_{de}, expressed as a percentage of Q_{eff}, provided as an output of the first artificial neural network 28, is applied to a differentiator 42, and the resulting time derivative Of Q_{de} (dQ_{de}/dt) is supplied as the feedback input to the second artificial neural network 40. For a given temperature and current, if we have a good estimate for Q_{de}, then it should be the case that this estimate will remain relatively constant, i.e. that dQ_{de}/dt≈0. By contrast, a negative value for dQ_{de}/dt would suggest that the initial estimate for Q_{de}, and hence for Q_{eff}, was too high, while a positive value for dQ_{de}/dt would suggest that the initial estimate for Q_{de}, and hence for Q_{eff}, was too low. Thus, feeding back the value for the time derivative of Q_{de} allows the estimate Of Q_{eff} to be improved.

In another embodiment of the invention, the estimated value for Q_{de} itself can also be fed back to the second artificial neural network 40.

Where the state vector 32 is obtained by estimating the relevant parameters, without using a second artificial neural network, then the value of dQ_{de}/dt can again be used in a feedback loop to adjust the estimate for Q_{eff}, as discussed above.

As mentioned above, the first artificial neural network 28 is used to estimate the total charge available in the cell at the start of the ongoing discharge operation (Q_{de}), expressed as a percentage of Q_{eff}, and this is provided as a first input to a multiplier 44. The value of Q_{eff} itself, in this case estimated by the second artificial neural network 40, is provided as a second input to a multiplier 44. The output of the multiplier 44 is therefore an estimate of the actual value for the total charge available in the cell at the start of the ongoing discharge operation.

This estimated value for the total charge available in the cell at the start of the ongoing discharge operation is provided as a first input to an adder 46, which receives the Coulomb counted value for the charge drawn during the ongoing discharge operation (Q_{CC}) as a second input value, and subtracts that second input value from its first input.

The resulting output value from the adder 46 is the estimate for the state of charge (Q_{D}) of the battery 14.

Thus, given that all of the parameter values are time-varying:

Q_{D}(t)=Q_{de}(t)−Q_{CC}(t),

where Q_{D}(t) is the estimate for the state of charge at a time t, Q_{de}(t) is the estimate at the time t of the total charge available in the cell at the start of the ongoing discharge operation, and Q_{CC}(t) is the Coulomb counted value for the charge drawn during the ongoing discharge operation up to the time t.

This allows an accurate value for the state of charge (SoC) parameter Q_{D} to be estimated, and provided as an output of the system.

Since the neural network 28 is used to estimate a parameter value that changes only relatively slowly, noise in the estimation of the parameter value can be reduced by averaging methods. For example, either the value of Q_{de} output from the neural network 28 or the value for the state of charge (SoC) parameter Q_{D} can conveniently be averaged over time, for example by low-pass filtering, before being used further.

As mentioned above, the value for the state of charge parameter can be output (possibly after low-pass filtering) to a fuel gauge 22 for display to the user of the device, or for use by other elements of the battery management system.

In addition, the effective capacity of the battery 14 (Q_{eff}) is provided as a further output of the system. Again, the value for the effective capacity of the battery can be output to the fuel gauge 22 for display to the user of the device, or for use by other elements of the battery management system. Any or all of the other state of health parameter values generated by the second neural network 40 can also be provided as system outputs, if required.

Thus, in the illustrated embodiment shown in FIG. 2, an output of the first neural network 28 is provided as an input to the second neural network 40, while an output of the second neural network 40 is provided as an input to the first neural network 28.

However, in a simplified system in accordance with the invention, there is no second neural network, and a stored constant value is available for the effective capacity of the battery 14 (Q_{eff}). It is this stored value that is used by the first neural network 28 to estimate the total charge available in the cell at the start of the ongoing discharge operation (Q_{de}), and hence allows an estimate of the state of charge (Q_{D}) of the battery 14.

As described above, the system relies on a periodic determination that the battery 14 has been fully recharged, allowing an estimate of the state of charge of the battery to be obtained by subtracting the amount of charge drawn, since the last full recharging operation, from an estimate of the total charge available in the cell following that last full recharging operation, i.e. at the start of the ongoing discharge operation. However, the invention is also applicable to systems, for example as used in hybrid electric vehicles (HEVs), where the battery 14 is rarely or never fully recharged, but is continuously being partially discharged and then partially recharged, depending on the operating conditions of the vehicle.

In such a system, it is necessary to define one or more reference points, that would be expected to be reached relatively frequently during the recharging phase of the cycle. For example, when a particular combination of input parameter values (for example, voltage and current) is reached, it can be determined that a reference point has been reached, without needing to assume that the battery is fully charged at this point. The reset generator can be triggered at this point, and the charging and discharging currents can then be integrated to arrive at a value for the net amount of charge drawn from the battery since this reference point was last reached. Meanwhile, the neural network can be used to estimate the available charge in the battery at this reference point, and the net amount of charge drawn can be subtracted from the present estimated value of the available charge in the battery at the reference point, in order to form the estimate of the state of charge.

There is thus provided a system that allows the state of charge and state of health of a battery to be estimated accurately, and therefore allows more efficient use of rechargeable battery systems.

1. A method of estimating a state of charge of a battery, comprising:
using a first neural network to form an estimate of a remaining amount of charge following a previous recharging operation;
measuring an amount of charge drawn from the battery since the previous recharging operation;
forming an estimate of the state of charge from the estimated remaining amount of charge and the amount of charge drawn.

2. A method as claimed in claim 1, comprising:
supplying at least one parameter representing a state of health of the battery as an input to the first neural network.

3. A method as claimed in claim 2, wherein the parameter representing the state of health of the battery represents the effective capacity of the battery.

4. A method as claimed in claim 3, wherein the parameter representing the state of health of the battery further represents the internal resistance of the battery.

5. A method as claimed in claim 3, wherein the parameter representing the state of health of the battery further represents a time constant of an equivalent circuit of the battery.

6. A method as claimed in claim 2, further comprising using a second neural network to form an estimate of the at least one parameter representing the state of health of the battery.

7. A method as claimed in claim 2, further comprising forming an estimate of the at least one parameter representing the state of health of the battery based on a series of measurements relating to operating parameters of the battery.

8. A method as claimed in claim 1, wherein the step of using the first neural network to form the estimate of the remaining amount of charge following a previous recharging operation comprises:
using the first neural network to form an estimate of a remaining amount of charge following a previous recharging operation, as a percentage of an effective capacity of the battery.

9. A method as claimed in claim 8, wherein the step of using the first neural network to form the estimate of the remaining amount of charge following a previous recharging operation further comprises:
multiplying said estimate of the remaining amount of charge following the previous recharging operation, as a percentage of an effective capacity of the battery, by a value for said effective capacity of the battery.

10. A method as claimed in claim 9, comprising using a second neural network to form said value for said effective capacity of the battery.

11. A method as claimed in claim 1, wherein the previous recharging operation is a full recharging operation.

12. A method as claimed in claim 1, wherein the previous recharging operation is a partial recharging operation.

13. A method as claimed in claim 1, further comprising:
providing an estimate of an effective capacity of the battery as an input to the first neural network; and
forming said estimate of the effective capacity of the battery based on said estimate of the remaining amount of charge following a previous recharging operation.

14. A method as claimed in claim 1, further comprising:
using a second artificial neural network to form said estimate of the effective capacity of the battery, and
providing a time derivative of said estimate of the remaining amount of charge following a previous recharging operation as an input to said second artificial neural network.

15. A battery management system, for estimating a state of charge of a battery, comprising:
a first neural network configured for forming an estimate of a remaining amount of charge following a previous recharging operation;
a mechanism operable to measure an amount of charge drawn from the battery since the previous recharging operation; and
a mechanism operable to form an estimate of the state of charge from the estimated remaining amount of charge and the amount of charge drawn.

16. A battery management system as claimed in claim 15, further comprising a mechanism operable to supply at least one parameter representing a state of health of the battery as an input to the first neural network.

17. A battery management system as claimed in claim 16, wherein the parameter representing the state of health of the battery represents the effective capacity of the battery.

18. A battery management system as claimed in claim 17, wherein the parameter representing the state of health of the battery further represents the internal resistance of the battery.

19. A battery management system as claimed in claim 17, wherein the parameter representing the state of health of the battery further represents a time constant of an equivalent circuit of the battery.

20. A battery management system as claimed in claim 16, further comprising a second neural network configured for forming an estimate of the at least one parameter representing the state of health of the battery.

21. A battery management system as claimed in claim 15, wherein the first neural network has been trained to form an estimate of a remaining amount of charge following a previous recharging operation, as a percentage of an effective capacity of the battery.

22. A battery management system as claimed in claim 21, further comprising a multiplier configured for multiplying said estimate of the remaining amount of charge following the previous recharging operation, as a percentage of an effective capacity of the battery, by a value for said effective capacity of the battery.

23. A battery management system as claimed in claim 21, further comprising a second neural network configured for forming said value for said effective capacity of the battery.

24. A battery management system as claimed in claim 15, further comprising a fuel gauge.

25. A battery management system as claimed in claim 24, wherein the fuel gauge provides a numerical display of a parameter

26. A battery management system as claimed in claim 24, wherein the fuel gauge provides a warning when the battery is nearly discharged.

27. A battery management system as claimed in claim 24, wherein the fuel gauge includes an analog display showing remaining battery capacity.

28. (canceled)

29. An electrochemical cell system including a battery and a battery management system, wherein the battery management system comprises:
a first neural network configured for forming an estimate of a remaining amount of charge in the battery following a previous recharging operation;
a mechanism operable to measure an amount of charge drawn from the battery since the previous recharging operation; and
a mechanism operable to form an estimate of the state of charge from the estimated remaining amount of charge and the amount of charge drawn.

30. An electrochemical cell system as claimed in claim 29, wherein the battery management system further comprises a mechanism operable to supply at least one parameter representing a state of health of the battery as an input to the first neural network.

31. An electrochemical system as claimed in claim 30, wherein the parameter representing the state of health of the battery represents the effective capacity of the battery.

32. An electrochemical cell system as claimed in claim 31, wherein the parameter representing the state of health of the battery further represents the internal resistance of the battery.

33. An electrochemical cell system as claimed in claim 31, wherein the parameter representing the state of health of the battery further represents a time constant of an equivalent circuit of the battery.

34. An electrochemical cell system as claimed in claim 30, wherein the battery management system further comprises a second neural network configured for forming an estimate of the at least one parameter representing the state of health of the battery.

35. An electrochemical cell system as claimed in claim 29, wherein the first neural network has been trained to form an estimate of a remaining amount of charge following a previous recharging operation, as a percentage of an effective capacity of the battery.

36. An electrochemical cell system as claimed in claim 35, wherein the battery management system further comprises a multiplier configured for multiplying said estimate of the remaining amount of charge following the previous recharging operation, as a percentage of an effective capacity of the battery, by a value for said effective capacity of the battery.

37. An electrochemical cell system as claimed in claim 35, wherein the battery management system further comprises a second neural network configured for forming said value for said effective capacity of the battery.

38. An electrochemical cell system as claimed in claim 29, wherein the battery management system further comprises a fuel gauge.

39. An electrochemical cell system as claimed in claim 38, wherein the fuel gauge provides a numerical display of a parameter

40. An electrochemical cell system as claimed in claim 38, wherein the fuel gauge provides a warning when the battery is nearly discharged.

41. An electrochemical cell system as claimed in claim 38, wherein the fuel gauge includes an analog display showing remaining battery capacity.
